(19) United States
(12) Patent Application Publication
(10) Pub. No.: US 2013/0205073 A1
(43) Pub. Date: Aug. 8, 2013

(54) MEMORY DEVICE, MEMORY SYSTEM, AND PROGRAMMING METHOD THEREOF

(71) Applicant: SAMSUNG ELECTRONICS CO., LTD., Suwon-Si (KR)

(72) Inventors: Nam-oh HWANG, Seoul (KR); Dong-hyun SONG, Hwaseong-si (KR); Han-chan JO, Yongin-si (KR)

(73) Assignee: SAMSUNG ELECTRONICS CO., LTD., Suwon-Si (KR)

(21) Appl. No.: 13/751,351

(22) Filed: Jan. 28, 2013

(30) Foreign Application Priority Data
Jan. 30, 2012 (KR) 10-2012-0009208

(51) Int. Cl. G11C 16/10

(52) U.S. Cl. CPC G11C 16/10
USPC 711/103; 365/185.03; 365/185.18; 711/154

(57) ABSTRACT

A memory device, a memory system, and a programming method thereof. The memory system includes a memory controller configured to set first type offset information corresponding to a first type of data and set second type offset information corresponding to a second type of data; and a memory device configured to receive the first type offset information to program the first type of data in a first type of page that is read at a first speed and receive the second type offset information to program the second type of data in a second type of page that is read at a second speed, the first speed being different from the second speed.

### CROSS-REFERENCE TO RELATED APPLICATIONS

This application claims the benefit of Korean Patent Application No. 10-2012-0009208, filed on Jan. 30, 2012, in the Korean Intellectual Property Office, the disclosure of which is incorporated herein in its entirety by reference.

### BACKGROUND

The inventive concepts relate to a memory device, a memory system, and/or a programming method thereof, and more particularly, to a memory device, a memory system, and/or a programming method thereof that may improve performance of a device and/or a system.

As memory devices become small and highly integrated, a data reading speed of the memory device greatly affects performance of the memory device or a memory system.

### SUMMARY

The inventive concepts provide a memory device, a memory system, and/or a programming method thereof that may improve performance of a device and/or a system.

According to at least one example embodiment, a memory system comprises a memory controller configured to set first type offset information corresponding to a first type of data and set a second type offset information corresponding to a second type of data; and a memory device configured to receive the first type offset information to program the first type of data in a first type of page that is read at a first speed and receive the second type offset information to program the second type of data in a second type of page that is read at a second speed, the first speed being different from the second speed.

According to at least one example embodiment, the first type of data is more frequently accessed in the memory device than the second type of data.

According to at least one example embodiment, the first type of data requires a rapid programming time or a rapid reading time compared to the second type of data.

According to at least one example embodiment, the first speed is greater than the second speed.

According to at least one example embodiment, a time to read the first type of page is shorter than a time to read the second type of page.

According to at least one example embodiment, the memory device includes a plurality of blocks, and the first type of page and the second type of page are in different blocks from among the plurality of blocks.

According to at least one example embodiment, the memory device includes a plurality of blocks, and the first type of page and the second type of page are in a same block from among the plurality of blocks.

According to at least one example embodiment, the memory controller includes a counter configured to count a requested access frequency of data, and the memory controller is configured to classify the data into the first type of data and the second type of data according to a result of the counter.

According to at least one example embodiment, the memory device is a multi-level cell (MLC) NAND flash memory, and the memory system is a solid state drive (SSD).

According to at least one example embodiment, the first type of page and the second type of page are configured to share a same word line of the memory device, and a number of reading operations for distinguishing data of the first type of page is less than a number of reading operations for distinguishing data of the second type of page.

According to at least one example embodiment, the first speed and the second speed correspond to programming times of the first type of page and the second type of page.

According to at least one example embodiment, a programming method of an MLC NAND flash memory device comprises programming a first type of data in a first type of page that is read at a first speed according to first type offset information; and programming a second type of data in a second type of page that is read at a second speed according to second type offset information.

According to at least one example embodiment, a time to read the first type of page is less than a time to read the second type of page.

According to at least one example embodiment, the first type of page and the second type of page share a same word line of the memory device, and a number of reading operations for distinguishing data of the first type of page is less than a number of reading operations for distinguishing data of the second type of page.

According to at least one example embodiment, the NAND flash memory device is in a solid state drive (SSD), and the first type offset information and the second type offset information are transmitted from a memory controller in the SSD.

According to at least one example embodiment, a memory device comprises a memory array including at least one memory block; and a control logic configured to program first data and second data into the at least one memory block, the first data being programmed into a first page of the at least one memory block, the second data being programmed into a second page of the at least one memory block, the first data being accessed more frequently than the second data in the at least one memory block.

According to at least one example embodiment, the control logic is configured to program the first data according to first offset information, and program second data according to second offset information, the first offset information corresponding to characteristics of the first page, and the second offset information corresponding to characteristics of the second page.

According to at least one example embodiment, wherein the characteristics of the first page relate to a number of operations required to read the first data, and the characteristics of the second page relate to a number of operations required to read the second data.

According to at least one example embodiment, the number of operations required to read the first data is less than the number of operations required to read the second data.

According to at least one example embodiment, the first and second pages share a same word line in the memory array, and the control logic is configured to program the first data into a region including a least significant bit of the word line, and the control logic is configured to program the second data into a region including a most significant bit of the word line.

### BRIEF DESCRIPTION OF THE DRAWINGS

Exemplary embodiments of the inventive concepts will be more clearly understood from the following detailed description taken in conjunction with the accompanying drawings in which:

FIG. 1 is a schematic block diagram of a memory system according to at least one example embodiment of the inventive concepts;

FIG. 2 is a diagram showing an memory controller of FIG. 1;

FIG. 3 is a conceptual diagram of a firmware of FIG. 2;

FIG. 4 is a diagram showing a structure of a memory cell array included in the memory device of FIG. 1;

FIG. 5 is a view showing a block shown in FIG. 4;

FIGS. 6A-6C are graphs showing program states according to types of the memory device of FIG. 1;

FIG. 7 is a table showing a relationship between word lines and pages of the memory device of FIG. 1;

FIG. 8 is a diagram showing a structure of a memory device to describe a programming operation according to at least one example embodiment of the inventive concepts;

FIG. 9 is a flowchart for describing a programming operation of the memory device of FIG. 8;

FIG. 10 is a diagram showing an example where data is programmed in the memory device of FIG. 1 or 8;

FIG. 11 is a diagram showing an example where data is programmed according to properties of the data in the memory device of FIG. 1;

FIGS. 12 and 13 are diagrams showing examples where data is programmed in the memory device of FIG. 1 or 8 according to at least one example embodiment of the inventive concepts;

FIG. 14 is a diagram showing a structure in which the memory controller of FIG. 1 may classify data according to properties of the data;

FIG. 15 is a diagram of a computer device according to at least one example embodiment of the inventive concepts; and

FIG. 16 is a diagram showing a server system and a network system according to at least one example embodiment of the inventive concepts.

### DETAILED DESCRIPTION OF EXAMPLE EMBODIMENTS

Hereinafter, the inventive concepts will be described in detail by explaining embodiments of the inventive concepts with reference to the attached drawings.

The inventive concepts may, however, be embodied in many different forms and should not be construed as being limited to the example embodiments set forth herein; rather, these example embodiments are provided so that this disclosure will be thorough and complete, and will fully convey the inventive concepts to one of ordinary skill in the art.

The terminology used herein is for the purpose of describing particular embodiments and is not intended to limit the inventive concepts. As used herein, the singular forms “a”, “an”, and “the” are intended to include the plural forms as well, unless the context clearly indicates otherwise. It will be further understood that the terms “comprises” and/or “comprising,”, “includes”, and/or “including” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the inventive concepts.

Hereinafter, example embodiments of the inventive concepts will be described with reference to accompanying drawings schematically illustrating the example embodiments. In the drawings, for example, illustrated shapes may be deformed according to fabrication technology and/or tolerances. Therefore, the example embodiments of the inventive concepts are not limited to certain shapes illustrated in the present specification, and may include modifications or deviations of shapes caused in fabrication processes.

As used herein, expressions such as “at least one of,” when preceding a list of elements, modify the entire list of elements and do not modify the individual elements of the list.

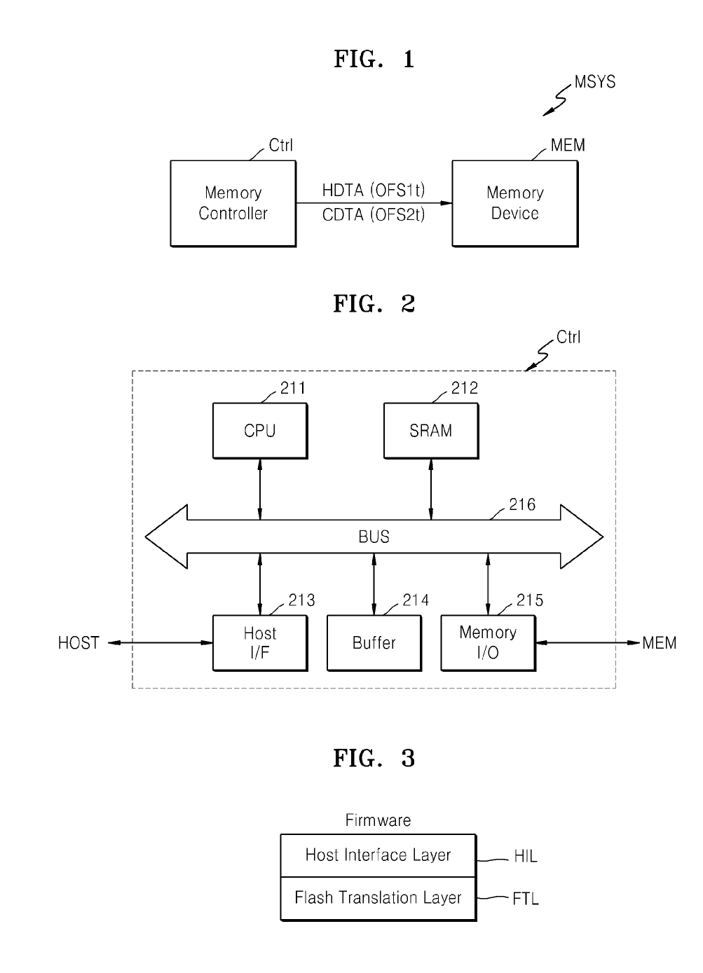

FIG. 1 is a schematic block diagram of a memory system MSYS according to at least one example embodiment of the inventive concepts.

The memory system MSYS includes a memory controller Ctrl and a memory device MEM. The memory controller Ctrl sets first type offset information OFS1t with respect to a first type of data HDTA and sets second type offset information OFS2t with respect to a second type of data CDTA.

The first type of data HDTA may be data that is frequently accessed in the memory device MEM. The second type of data CDTA may be data that is less frequently accessed in the memory device MEM compared to the first type of data HDTA. Accordingly, the first type of data HDTA and the second type of data CDTA may be referred to as hot data and cold data, respectively.

For example, the first type of data HDTA may be meta data for the memory device MEM, and the second type of data CDTA may be user data. However, the first type of data HDTA and the second type of data CDTA are not limited to the meta data and the user data, respectively. Also, irrespective of access frequency, the first type of data HDTA may be data that requires a relatively rapid read time or a relatively rapid programming time, and the second type of data CDTA may be data that does not require a relatively rapid read time or a relatively rapid programming time compared to the first type of data. The first type offset information OFS1t and the second type offset information OFS2t include information regarding a property of an area where data is programmed in the memory device MEM, which will be described later.

Referring to FIG. 1, the memory system MSYS may be a solid state drive (SSD). In this case, the memory controller Ctrl may include a structure as shown in FIG. 2. However, the memory system MSYS is not limited to the SSD, and may be a secure digital (SD) card, an embedded multimedia card (eMMC), or the like.

FIG. 2 is a diagram showing the memory controller Ctrl of FIG. 1.

Referring to FIG. 2, in the memory controller Ctrl, a host interface unit 213, a memory interface unit 215, a static random access memory (SRAM) 212, a buffer unit 214, and a processor 211 may be connected to a bus 216. The host interface unit 213 may provide an interface to an external host device HOST.

For example, the host interface unit 213 may provide an interface of an SATA or an SAS protocol to the host device HOST. However, the inventive concepts are not limited thereto, and the host interface unit 213 may provide an interface to various interface protocols such as universal serial bus (USB), man machine communication (MMC), peripheral component interconnect-express (PCI-E), parallel advanced technology attachment (PATA), small computer system interface (SCSI), enhanced small device interface (ESDI), or intelligent drive electronics (IDE).

The memory interface unit 215 may provide an interface to the memory device MEM to program or read data requested by the host device HOST. For example, the memory interface unit 215 may provide a result of converting a logical block address transmitted from the host device HOST into a physical address with respect to a page of the memory device MEM, which may be a flash memory, to the memory device MEM.

Operations between the host device HOST and the memory device MEM may be performed by a firmware included in the SRAM 212 under the control of the processor 211. For example, the firmware may, as shown in FIG. 3, include a host interface layer HIL and a flash translation layer FTL. The host interface layer HIL processes a command received from the host device HOST. The flash translation layer FTL may perform controlling and resource assigning for mapping an address received from the host device HOST and a physical address of the memory device MEM according to the command that is processed by the host interface layer HIL. The buffer unit 214 for performing data buffering required for the mapping operation, etc., may be configured as a dynamic random access memory (DRAM).

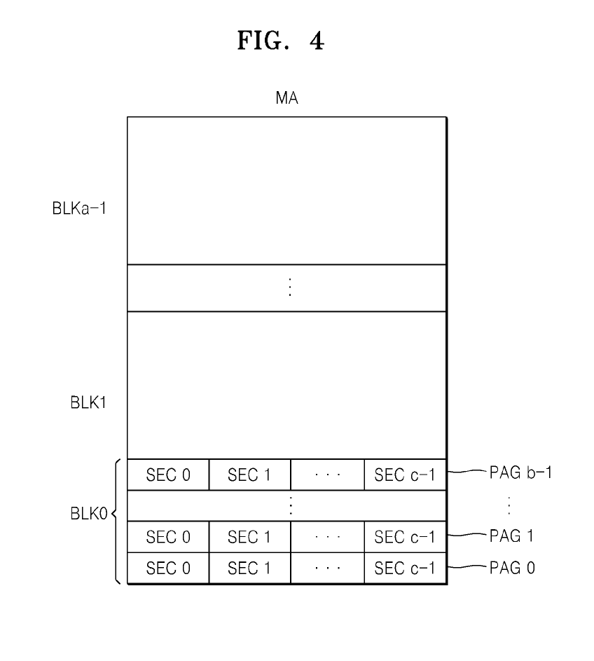

The memory device MEM of the memory system MSYS may include a memory cell array MA having a structure as shown in FIG. 4. The memory cell array MA may include a-blocks BLK0 to BLKa-1, wherein “a” is an integer greater than or equal to 2. Each of the blocks BLK0 to BLKa-1 may include b-pages PAG0 to PAGb-1, wherein “b” is an integer greater than or equal to 2. Each of the pages PAG0 to PAGb-1 may include c-sectors SEC0 to SECc-1, wherein “c” is an integer greater than or equal to 2. FIG. 4, for convenience of description, shows the pages PAG0 to PAGb-1 and the sectors SEC0 to SECc-1 only for the block BLK0, but other blocks may have the same structures as the block BLK0.

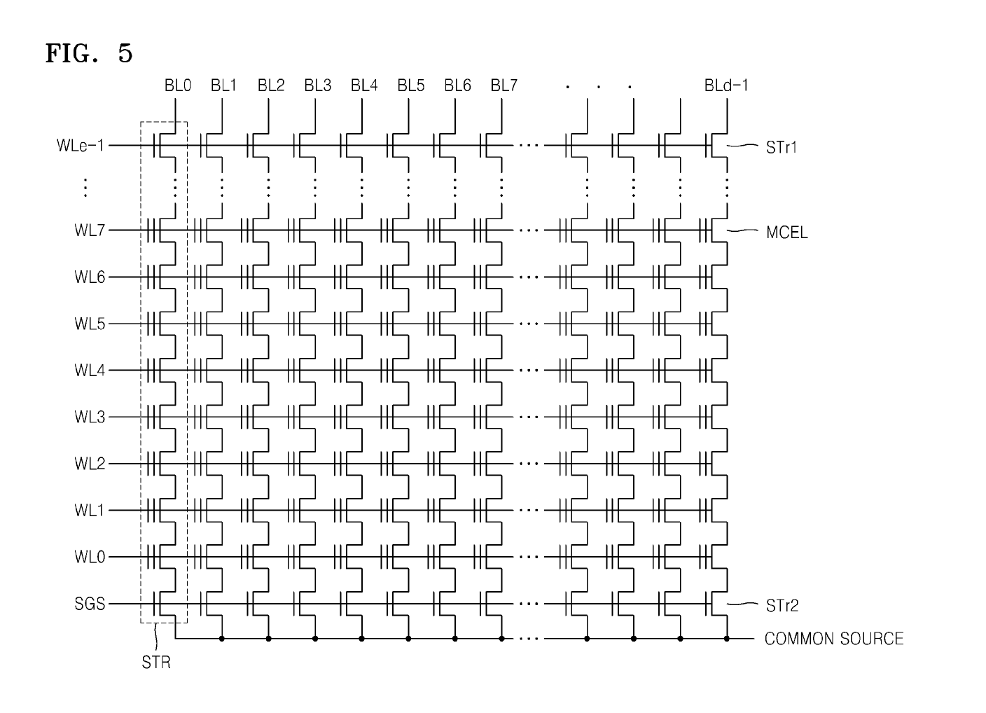

When the memory cell array MA is a memory cell array of a NAND flash memory device as described above, each of the blocks BLK0 to BLKa-1 of FIG. 4 may be structured as shown in FIG. 5. Referring to FIG. 5, each of the blocks BLK0 to BLKa-1 may include d-strings STR to which e-memory cells MCEL are connected in series in a direction in which a plurality of bit lines BL0 to BLd-1 are arranged, wherein “d” is an integer equal to or greater than 2. Each string may include a drain selection transistor Str1 and a source selection transistor Str2 that are connected to both ends of the memory cells MCEL.

In the NAND flash memory device having a structure as shown in FIG. 5, an erasing operation is performed in units of blocks and a programming operation is performed in units of pages corresponding to each of word lines WL0 to WLe-1. The memory device MEM of FIG. 1 may include a plurality of memory cell arrays having the same structure and performing the same operation as the above-described memory cell array MA.

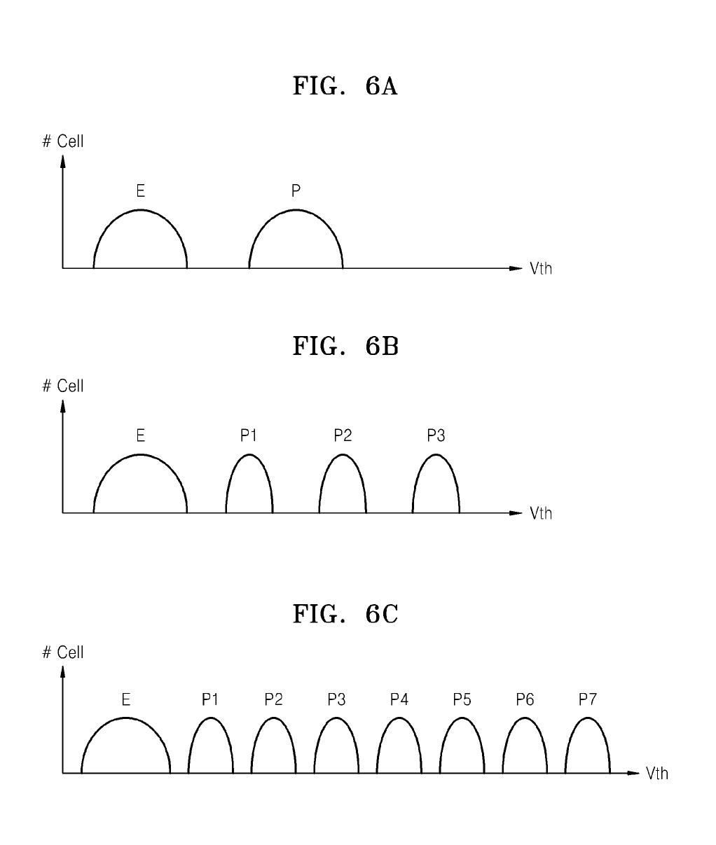

One or more pages may be set in each word line of FIG. 5. In other words, one or more pages may be programmed in each word line. For example, when the memory device MEM is a single-level cell (SLC) NAND flash memory device capable of programming one bit with respect to each memory cell as shown in FIG. 6A, one page may be set in each word line. When the memory device MEM is a multi-level cell (MLC) NAND flash memory device capable of programming two or more bits with respect to each memory cell as shown in FIG. 6B or FIG. 6C, two or more pages may be set in each work line. However, in the MLC NAND flash memory, at least one block may be set as an SLC block from among a plurality of blocks included in the memory cell array MA as shown in FIG. 4.

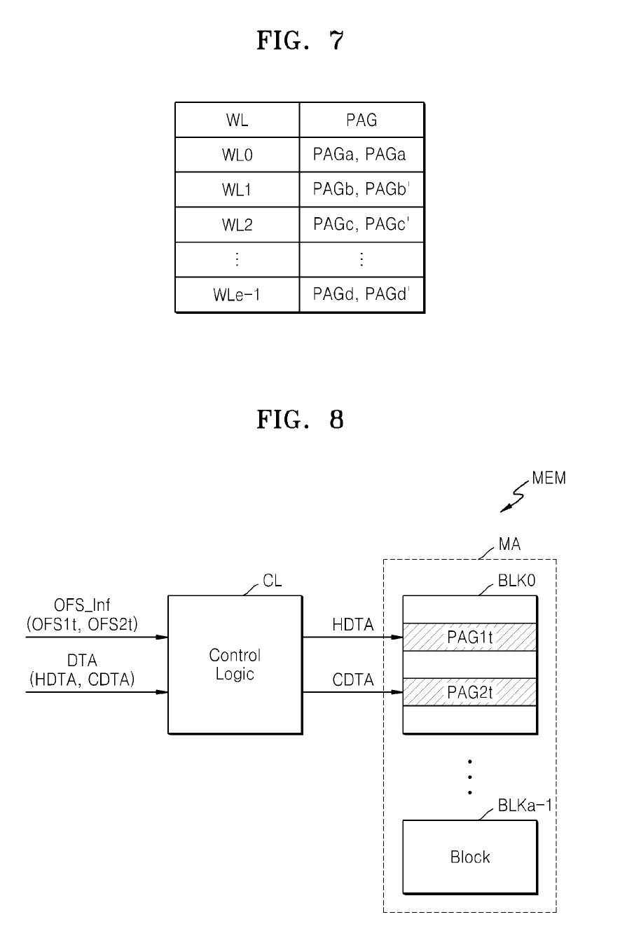

FIG. 7 is a table showing an example where a page is set with respect to each word line of the memory device MEM of FIG. 1.

Referring to FIGS. 1, 5, and 7, the memory device MEM be a 2-bit MLC NAND flash device. In this case, a page a PAGa and a page a′ PAGa′ may be set with respect to the word line 0 WL0 of the memory device MEM, a page b PAGb and a page b′ PAGb′ may be set with respect to the word line 1 WL1, and a page c PAGc and a page c′ PAGc′ may be set with respect to the word line 2 WL2.

In FIG. 7, a, b, and c may be 0, or consecutive or non-consecutive natural numbers. For example, a may be 0, b may be 1, and c may be 2. Also, in FIG. 7, a, b, and c may be set to have a multiple relationship. For example, when a is 1, a′ may be 2. Also, when a is 1 and b is 3, a′ may be 2 and b′ may be 6. A page d PAGd and a page d′ PAGd′ for the word line e-1 WLe-1 may be set in the same manner.

As shown in FIG. 7, in the 2-bit MLC NAND flash device, when two pages are set for each word line, a difference between reading speeds of two pages sharing the same word line may result from a difference in a number of times required to read the pages.

For example, in the 2-bit MLC NAND flash device, each word line may be shared by a least significant bit (LSB) page, which is read at a reading voltage having a voltage level between a program state P1 and a program state P2 of FIG. 6B, and a most significant bit (MSB) page, which is read at a reading voltage having a voltage level between an erase state E and the program state P1 and at a reading voltage having a voltage level between the program state P2 and a program state P3.

For example, the word line 0 WL0 of FIG. 7 may be shared by an LSB page PAGa and an MSB page PAGa′, the word line 1 WL1 may be shared by an LSB page PAGb and a MSB page PAGb′, and the word line 2 WL2 may be shared by an LSB page PAGc and a MSB page PAGc′. Similarly, the word line e-1 WLe-1 may be shared by an LSB page PAGd and an MSB page PAGd′.

In the above-described example, only a single reading voltage is required to read the LSB page, while two reading voltages are required to read the MSB page. In this case, only a single reading operation is required to read the LSB page, while two reading operations are required to read the MSB page. Thus, reading speeds required to read the LSB page and the MSB page may be different.

In the memory system MSYS according to at least one example embodiment, a first type of data and a second type of data classified according to data properties may be programmed in the corresponding pages from among the pages having different properties to improve reading characteristics and decrease latency of the memory device MEM or the memory system MSYS. A structure and operations of the memory device MEM according to at least one example embodiment will be described in detail below.

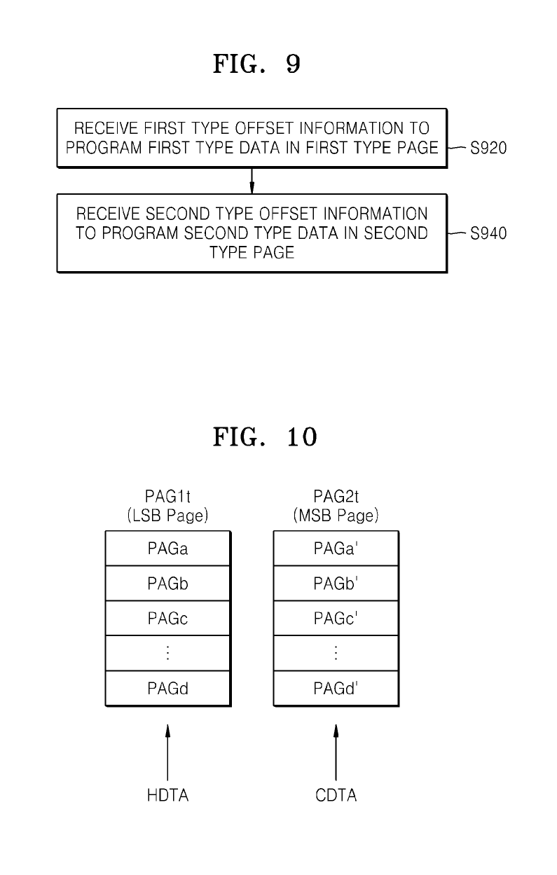

FIGS. 8 and 9 are diagrams showing a structure of a memory device MEM and a programming method thereof according to at least one example embodiment of the inventive concepts.

Referring to FIGS. 8 and 9, the memory device MEM of FIG. 8 includes a control logic CL for controlling data DTA to be programmed in a storing area corresponding to the memory cell array MA according to offset information OFS_Inf. The offset information OFS_Inf may include a first type offset information OFSlt and a second type offset information OFS2t. The data DTA may include a first type of data HDTA and a second type of data CDTA.

The memory device MEM of at least one example embodiment performs programming through the following operations, which are similar to the memory device MEM of FIG. 1. The memory device MEM receives the first type offset information OFSlt to program the first type of data HDTA in a first type of page PAG1t (operation S920), and receives a second type offset information OFS2t to program the second type of data CDTA in a second type of page PAG2t (operation S940). If the memory device MEM of FIG. 8 is included in a memory system MSYS similar to FIG. 1 or included in an SSD similar to FIG. 2, the first type offset information OFSlt and the second type offset information OFS2t may be transmitted from a memory controller Ctrl.

The first type offset information OFS1t may indicate that a page in which data is to be programmed is the first type of page PAG1t that is read at a first speed. Similarly, the second type offset information OFS2t may indicate a page in which data is to be programmed is the second type of page PAG2t that is read at a second speed.

In FIG. 7, the memory device MEM may program the first type of data HDTA in the LSB page which is the first type of page PAG1t and program the second type of data CDTA in the MSB page which is the second type of page PAG2t as shown in FIG. 10. The first type of page PAG1t and the second type of page PAG2t are separated from each other in FIG. 10. However, this is just for distinguishing the first type of page PAG1t and the second type of page PAG2t from each other, and the inventive concepts are not limited thereto.

In the above-described example, the first speed may be higher than the second speed. As described above, a difference between reading speeds of the first type of page PAG1t and the second type of page PAG2t may be related to the required number of reading operations. For example, when the number of reading operations required to read data of the corresponding page is relatively small, a reading speed of the corresponding page may be relatively high. On the other hand, when the number of reading operations required to read data of the corresponding page is relatively great, the reading speed of the corresponding page may be relatively low. For example, since the number of reading operations required to read the first type of page PAG1t is smaller than the number of reading operations required to read the second type of page PAG2t, time to read the first type of page PAG1t may be relatively short. Accordingly, for example, only a single reading operation is required to read the LSB page, while two reading operations are required to read the MSB page in the 2-bit MLC NAND flash device, and thus a reading speed of the LSB page may be higher than that of the MSB page.

According to the memory device MEM of at least one example embodiment, data having a frequent access speed may be stored in a page having a high reading speed, thereby improving a reading performance of the memory device MEM and improving the whole performance of the memory device MEM accordingly.

Referring back to FIG. 8, the first type of page PAG1t in which the first type of data HDTA is programmed and the second type of page PAG2t in which the second type of data CDTA is programmed may be included in the same block. FIG. 8 shows an example where the first type of data HDTA and the second type of data CDTA are programmed in different pages of the same block. However, the inventive concepts are not limited thereto.

Referring to FIGS. 5-8, it should be understood that a memory array MEM may include at least one memory block BLK0 and a control logic CL. The control logic CL is configured to program first data (e.g., HDTA) and second data (e.g., CDTA) into the at least one memory block BLK0. Accordingly, the first data may be accessed more frequently than the second data in the at least one memory block. Further, the first data may be programmed into a first page of the at least one memory block, and the second data may be programmed into a second page of the at least one memory block.

Still referring to FIGS. 5-8, according to at least one example embodiment, the first and second pages (e.g., PAGa and PAGa′) share a same word line (e.g., WL0) in the memory array MA. In this case, the control logic CL may program the first data into a region including the least significant bit of the word line, and the control logic CL may program second into a region including the most significant bit the word line.

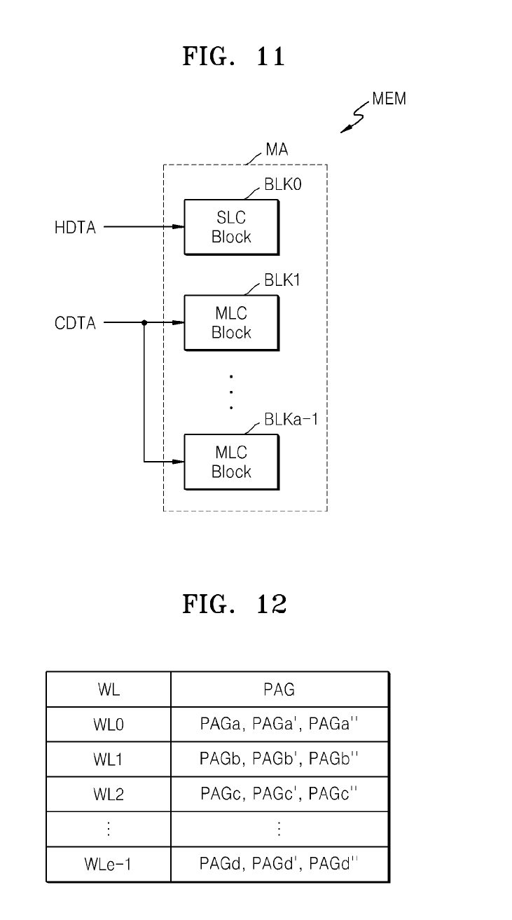

In the memory device MEM according to at least one example embodiment, as shown in FIG. 11, the first type of data HDTA may be programmed in an arbitrary block, for example, BLK0, from among the plurality of blocks BLK0 to BLKe-1 included in the memory cell array MA, and the second type of data CDTA may be programmed in a block different from the block in which the first type of data HDTA is programmed. FIG. 11 shows an example where the first type of data HDTA is programmed in the first type of page included in the SLC block and the second type of data CDTA is programmed in the MCL blocks BLK1 to BLKa-1. The memory device MEM is not limited to the number and positions of the SLC blocks shown in FIG. 11.

In the above description, the 2-bit MLC flash memory device has been described. However, the inventive concepts are not limited thereto. For example, the memory device MEM may be an MLC NAND flash memory device having at least 3 bits.

When the memory device MEM of the current embodiment is an MLC NAND flash memory device having at least 3 bits, three pages may be shared in each word line. For example, a page a PAGa, a page a′ PAGa′, and a page a″ PAGa″ may be set with respect to the word line 0 WL0 of the memory device MEM, a page b PAGb, a page b′ PAGb′, and a page b″ PAGb″ may be set with respect to the word line 1 WL1, and a page c PAGc, a page c′ PAGc′, and a page c″ PAGc″ may be set with respect to the word line 2 WL2. A page d PAGd, a page d′ PAGd′, and a page d″ PAGd″ may be set with respect to the word line e-1 WLe-1 in the same manner.

In a 3-bit MLC flash memory device, three pages shared in each word line may be an LSB page that is read at a reading voltage having a voltage level between a program state P3 and a program state P4 of FIG. 6C, a common significant bit (CSB) page that is read at reading voltages having a voltage level between a program state P1 and a program state P2 of FIG. 6C and a voltage level between a program state P5 and a program state P6, and an MSB page that is read at a reading voltages having a voltage level between the program state P1 and the program state P2 and a voltage level between the program state P5 and the program state P6, respectively. For example, in FIG. 12, a word line 0 WL0 may be shared by an LSB page PAGa, a CSB page PAGa′, and an MSB page PAGa″, a word line 1 WL1 may be shared by an LSB page PAGb, a CSB page PAGb′, and an MSB page PAGb″, and a word line 2 WL2 may be shared by an LSB page PAGc, a CSB page PAGc′, and an MSB page PAGc″. Similarly, a word line e-1 WLe-1 may be shared by an LSB page PAGd, a CSB page PAGd′, and an MSB page PAGd″.

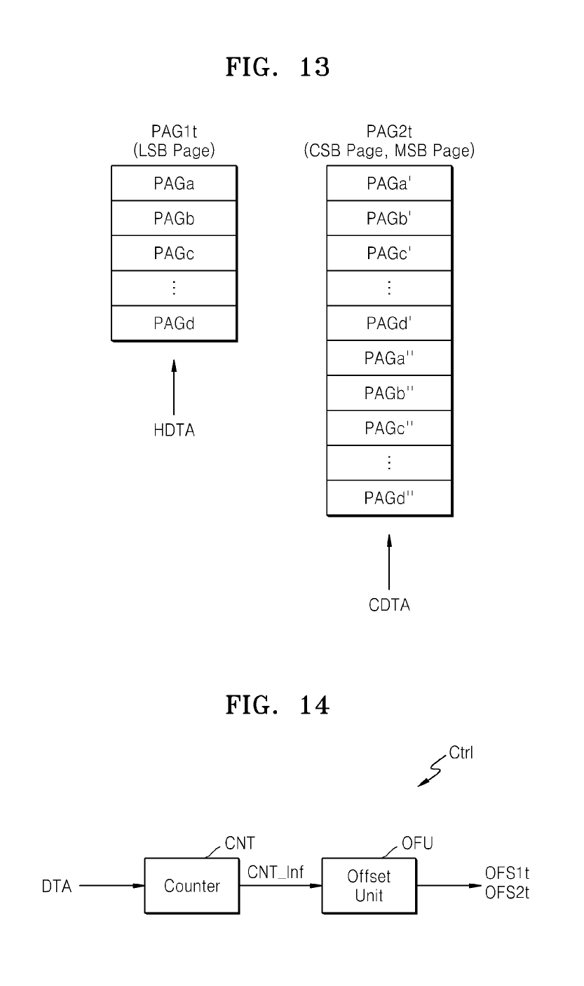

In the above-described example, as shown in FIG. 13, the LSB page of the memory device MEM may be the first type of page PAG1t, and the CSB page and the MSB page may be the second type of page PAG2t.

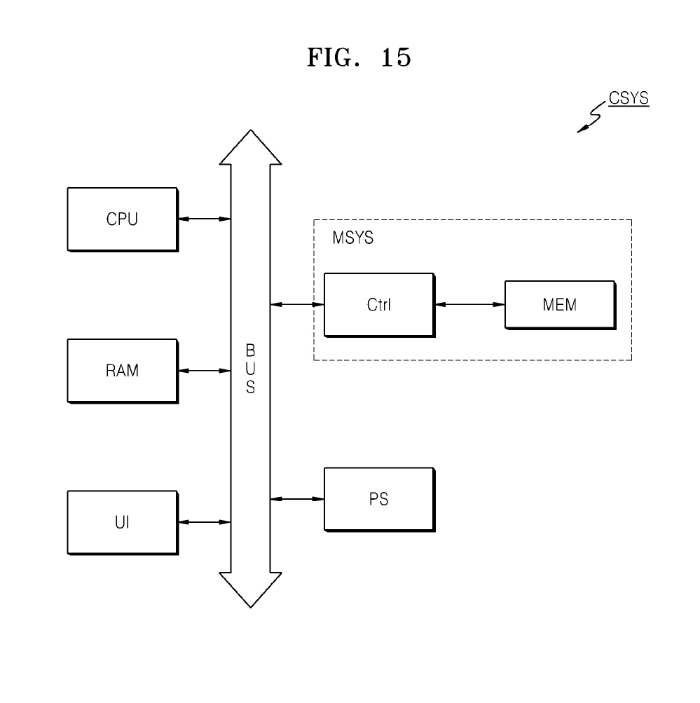

FIG. 14 shows a structure in which the memory controller Ctrl of FIG. 1 may classify data according to properties of data. However, program states and pages may be set according to the design of an NAND flash memory.

Referring to FIGS. 1 and 14, the memory controller Ctrl of FIG. 1 may include a counter CNT for counting an access frequency of data DTA requested by, for example, a host (not shown). The memory controller Ctrl may further include an offset setting unit OFU for generating the first type offset information OFS1t and the second type offset information OFS2t representing that the data DTA is assigned in which one between the first type of page PAG1t and the second type of page PAG2 according to a counting result CNT_Inf of the counter CNT.

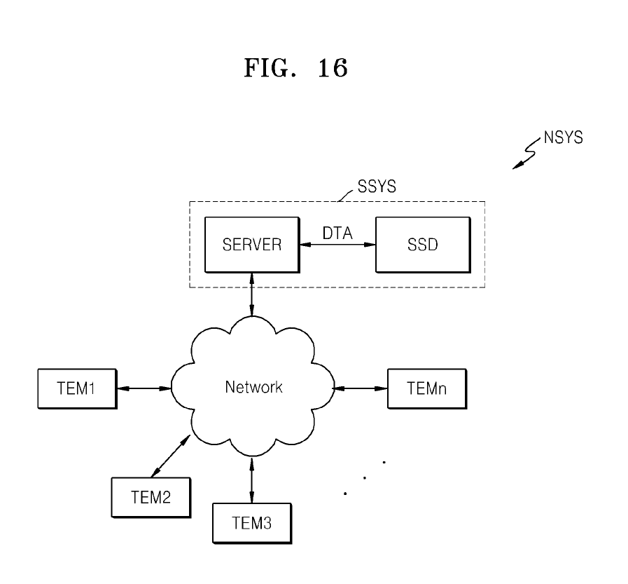

FIG. 15 is a diagram of a computer system CSYS according to at least one example embodiment of the inventive concepts.

Referring to FIG. 15, the computer system CSYS includes a processor CPU, a user interface UI, and a memory system MSYS that are electrically connected to a bus BUS. The memory system MSYS may be the memory system MSYS of FIG. 1. The memory device MEM included in the memory system MSYS may be the memory device MEM of FIG. 1 or 8. According to the computer system CSYS, performance of the computer system CSYS may be improved by increasing a data reading speed with respect to the memory device MEM.

The computer system CSYS may further include a power supply device PS. Also, the computer system CSYS may further include a volatile memory device, e.g., RAM, for sending/receiving data between the processor CPU and the memory system MSYS.

When the computer system CSYS is a mobile device, a battery and a modem, such as a baseband chipset for supplying an operation voltage of the computer system CSYS, may be additionally provided. The computer system CSYS may further include an application chipset, a camera image processor (CIS), a mobile DRAM, etc.

FIG. 16 is a diagram showing a server system SV_SYS and a network system NSYS according to at least one example embodiment of the inventive concepts.

Referring to FIG. 16, the network system NSYS may include the server system SV_SYS and a plurality of terminals TEM1 to TEMn that are connected to one another via a network. The server system SV_SYS may include a server SERVER connected to the network to process requests received from the terminals TEM1 to TEMn, and an SSD for storing data corresponding to the requests received from the terminals TEM1 to TEMn. According to at least one example embodiment, the SSD of FIG. 16 may be the memory system MSYS of FIG. 1 including the memory controller Ctrl of FIG. 2. The performance of the network system NSYS and the server system SV_SYS may be improved by increasing a data reading speed with respect to the SSD.

According to an example embodiment, when the reading speeds of the first type of page and the second type of page are different, programming speeds of the first type of page and the second type of page may be different and correspond to the difference in the reading speed. For example, in order to program an MSB page in the 2-bit MLC flash memory device as shown in FIG. 6B, the greater number of programming operations is required than a case an LSB page is programmed. Accordingly, programming speeds of the LSB page and the MSB page may be different in correspondence to the difference in reading speed.

According to a memory device, a memory system, and a programming method of the inventive concepts, a first type of data and a second type of data classified according to data properties may be programmed in the corresponding pages from among pages having different properties to improve the whole performance and decrease latency of the memory device or the memory system.

While the inventive concepts have been particularly shown and described with reference to exemplary embodiments thereof, it will be understood that various changes in form and details may be made therein without departing from the spirit and scope of the following claims.

1. A memory system comprising:
a memory controller configured to set first type offset information corresponding to a first type of data and set second type offset information corresponding to a second type of data; and
a memory device configured to receive the first type offset information to program the first type of data in a first type of page that is read at a first speed and receive the second type offset information to program the second type of data in a second type of page that is read at a second speed, the first speed being different from the second speed.

2. The memory system of claim 1, wherein the first type of data is more frequently accessed in the memory device compared to the second type of data.

3. The memory system of claim 1, wherein the first type of data requires a rapid programming time or a rapid reading time compared to the second type of data.

4. The memory system of claim 1, wherein the first speed is greater than the second speed.

5. The memory system of claim 1, wherein
a time to read the first type of page is shorter than a time to read the second type of page.

6. The memory system of claim 1, wherein the memory device includes a plurality of blocks, and the first type of page and the second type of page are in different blocks from among the plurality of blocks.

7. The memory system of claim 1, wherein the memory device includes a plurality of blocks, and the first type of page and the second type of page are in a same block from among the plurality of blocks.

8. The memory system of claim 1, wherein
the memory controller includes a counter configured to count a requested access frequency of data, and
the memory controller is configured to classify the data into the first type of data and the second type of data according to a result of the counter.

9. The memory system of claim 1, wherein the memory device is a multi-level cell (MLC) NAND flash memory, and the memory system is a solid state drive (SSD).

10. The memory system of claim 9, wherein the first type of page and the second type of page are configured to share a same word line of the memory device, and a number of reading operations for distinguishing data of the first type of page is less than a number of reading operations for distinguishing data of the second type of page.

11. The memory system of claim 1, wherein the first speed and the second speed correspond to programming times of the first type of page and the second type of page.

12. A programming method of an MLC NAND flash memory device, the programming method comprising:
programming a first type of data in a first type of page that is read at a first speed according to first type offset information; and
programming a second type of data in a second type of page that is read at a second speed according to second type offset information.

13. The programming method of claim 12, wherein a time to read the first type of page is less than a time to read the second type of page.

14. The programming method of claim 12, wherein the first type of page and the second type of page share a same word line of the memory device, and a number of reading operations for distinguishing data of the first type of page is less than a number of reading operations for distinguishing data of the second type of page.

15. The programming method of claim 12, wherein the NAND flash memory device is in a solid state drive (SSD), and the first type offset information and the second type offset information are transmitted from a memory controller in the SSD.

16. A memory device, comprising:
a memory array including at least one memory block; and
a control logic configured to program first data and second data into the at least one memory block, the first data being programmed into a first page of the at least one memory block, the second data being programmed into a second page of the at least one memory block, the first data being accessed more frequently than the second data in the at least one memory block.

17. The memory device of claim 16, wherein the control logic is configured to program the first data according to first offset information, and program the second data according to second offset information, the first offset information corresponding to characteristics of the first page, and the second offset information corresponding to characteristics of the second page.

18. A memory device of claim 17, wherein the characteristics of the first page relate to a number of operations required to read the first data, and the characteristics of the second page relate to a number of operations required to read the second data.

19. The memory device of claim 18, wherein the number of operations required to read the first data is less than the number of operations required to read the second data.

20. The memory device of claim 16, wherein the first and second pages are configured to share a same word line in the memory array, and the control logic is configured to program the first data into a region including a least significant bit of the word line, and the control logic is configured to program the second data into a region including a most significant bit of the word line.
